(19) United States
(12) Patent Application Publication
(10) Pub. No.: US 2023/0307439 A1
(43) Pub. Date: Sep. 28, 2023

(54) ESD PROTECTION CIRCUIT AND SEMICONDUCTOR DEVICE

(71) Applicant: ABLIC Inc., Tokyo (JP)

(72) Inventor: Tomomitsu RISAKI, Tokyo (JP)

(73) Assignee: ABLIC Inc., Tokyo (JP)

(21) Appl. No.: 18/183,164

(22) Filed: Mar. 14, 2023

(30) Foreign Application Priority Data
Mar. 24, 2022 (JP) 2022-047836
Mar. 24, 2022 (JP) 2022-047837

(51) Int. Cl. H01L 27/02; H02H 9/04

(52) U.S. Cl. CPC H01L 27/027; H01L 27/0288; H01L 27/0255; H02H 9/046

(57) ABSTRACT

An ESD protection circuit is connected in parallel with an internal circuit operating at a predetermined operating voltage between a V_{DD} terminal and a V_{SS} terminal, and includes an NMOS transistor in which an N type high concentration drain region is connected to the V_{DD} terminal and an N type high concentration source region is connected to the V_{SS} terminal. A threshold voltage and a trigger voltage of a parasitic bipolar transistor of the NMOS transistor are higher than the operating voltage and lower than a breakdown voltage of the internal circuit and a breakdown voltage of a gate insulating film of the NMOS transistor.

### CROSS-REFERENCE TO RELATED APPLICATIONS

This application claims the priority benefits of Japan Application No. 2022-047836, filed on Mar. 24, 2022, and Japan Application No. 2022-047837, filed on Mar. 24, 2022. The entirety of each of the above-mentioned patent applications is hereby incorporated by reference herein and made a part of this specification.

### BACKGROUND

### Technical Field

The present invention relates to an ESD protection circuit and a semiconductor device.

### Related Art

A semiconductor integrated circuit is vulnerable to electrostatic discharge (ESD) and may be easily damaged. Hence, the semiconductor integrated circuit often includes an ESD protection circuit which is for protecting an internal circuit from electrostatic discharge.

The ESD protection circuit may operate only when a surge voltage due to electrostatic discharge is applied to a power line or the like, and, before a surge current flows into the internal circuit, quickly allows the surge current to flow through a ground line or the like without damaging the ESD protection circuit itself, and protects the internal circuit.

Specifically, if a source of electrostatic discharge is a human body, before a surge voltage of several thousand volts due to electrostatic discharge reaches a breakdown voltage of the internal circuit, the ESD protection circuit allows a surge current of several amperes to flow to a ground potential or the like.

Examples of such an ESD protection circuit include a diode type ESD protection circuit using a breakdown phenomenon, a gate grounded metal oxide semiconductor (GG-MOS) type ESD protection circuit using a snapback operation performed by a parasitic bipolar transistor, and a capacitively coupled MOS type ESD protection circuit in which a MOS transistor turns on in response to application of a voltage having a short rise time.

For example, Japanese Patent Laid-open No. 2000-269437 proposes, as an example of the capacitively coupled MOS type ESD protection circuit, an ESD protection circuit in which a drain terminal and a source terminal of a MOS transistor are connected between an input pad and a V_{SS} terminal, and a gate terminal is connected with the input pad via a capacitor. In this capacitively coupled MOS type ESD protection circuit, since the capacitor between the input pad and the gate terminal functions as a high-pass filter, when static electricity is discharged to the input pad, a high frequency component of a surge voltage having a short rise time passes through the capacitor and reaches the gate terminal. Then, a potential of the gate changes, the MOS transistor is turned on, and the surge current flows to the V_{SS} terminal side, thereby protecting the internal circuit from electrostatic discharge.

### SUMMARY

One aspect of the present invention provides an ESD protection circuit which can be reduced in layout area and can be reduced in leakage current, and in which a malfunction can be prevented.

An ESD protection circuit in one embodiment of the present invention is an ESD protection circuit connected in parallel with a protected circuit which operates at a predetermined operating voltage between a first terminal and a second terminal. The ESD protection circuit includes an NMOS transistor in which at least a drain is connected to the first terminal and a source is connected to the second terminal. A threshold voltage, an avalanche breakdown voltage of a parasitic diode, and a trigger voltage of a parasitic bipolar transistor of the NMOS transistor are higher than the operating voltage and lower than a breakdown voltage of the protected circuit and a gate insulating film.

According to one aspect of the present invention, an ESD protection circuit can be provided which can be reduced in layout area and can be reduced in leakage current, and in which a malfunction can be prevented.

### BRIEF DESCRIPTION OF THE DRAWINGS

FIG. 1 is a circuit diagram illustrating an ESD protection circuit and a semiconductor device in a first embodiment of the present invention.

FIG. 2A is a schematic sectional view illustrating an example of a structure of an NMOS transistor in the first embodiment.

FIG. 2B is an explanatory diagram illustrating an example of an operation of an NMOS transistor in the first embodiment.

FIG. 2C is an explanatory diagram illustrating an example of an operation of an NMOS transistor in the first embodiment.

FIG. 2D is an explanatory diagram illustrating an example of an operation of an NMOS transistor in the first embodiment.

FIG. 2E is an explanatory diagram illustrating an example of an operation of an NMOS transistor in the first embodiment.

FIG. 2F is a graph illustrating an example of a current-voltage characteristic of an ESD protection circuit in the first embodiment.

FIG. 3A is a circuit diagram illustrating an ESD protection circuit in Modification 1 of the first embodiment.

FIG. 3B is a circuit diagram illustrating an ESD protection circuit in Modification 2 of the first embodiment.

FIG. 4A is a schematic sectional view illustrating another example of a structure of an NMOS transistor in the first embodiment.

FIG. 4B is a schematic sectional view illustrating still another example of an NMOS transistor in the first embodiment.

FIG. 4C is a schematic sectional view illustrating still another example of an NMOS transistor in the first embodiment.

FIG. 4D is a schematic sectional view illustrating still another example of an NMOS transistor in the first embodiment.

FIG. 4E is a schematic sectional view illustrating still another example of an NMOS transistor in the first embodiment.

FIG. 4F is a schematic sectional view illustrating still another example of an NMOS transistor in the first embodiment.

FIG. 4G is a schematic sectional view illustrating still another example of an NMOS transistor in the first embodiment.

FIG. 4H is a schematic sectional view illustrating still another example of an NMOS transistor in the first embodiment.

FIG. 5 is a circuit diagram illustrating an ESD protection circuit and a semiconductor device in a second embodiment of the present invention.

FIG. 6A is a schematic sectional view illustrating an example of a structure of an NMOS transistor in the second embodiment.

FIG. 6B is an explanatory diagram illustrating an example of an operation of an NMOS transistor in the second embodiment.

FIG. 6C is an explanatory diagram illustrating an example of an operation of an NMOS transistor in the second embodiment.

FIG. 6D is an explanatory diagram illustrating an example of an operation of an NMOS transistor in the second embodiment.

FIG. 6E is an explanatory diagram illustrating an example of an operation of an NMOS transistor in the second embodiment.

FIG. 6F is a graph illustrating an example of a current-voltage characteristic of an ESD protection circuit in the second embodiment.

FIG. 7A is a circuit diagram illustrating an example of a conventional diode type ESD protection circuit.

FIG. 7B is a graph illustrating an example of a current-voltage characteristic (by diode junction area) of a conventional diode type ESD protection circuit.

FIG. 8A is a circuit diagram illustrating an example of a conventional GG-MOS type ESD protection circuit.

FIG. 8B is a graph of a comparison of a current-voltage characteristic between a conventional diode type ESD protection circuit and a conventional GG-MOS type ESD protection circuit.

FIG. 8C is a graph of a comparison of a current-voltage characteristic between a conventional diode type ESD protection circuit and a conventional GG-MOS type ESD protection circuit when reduction of leakage current is not considered.

FIG. 8D is a graph of a comparison of a current-voltage characteristic between a conventional diode type ESD protection circuit and a conventional GG-MOS type ESD protection circuit when reduction of leakage current is considered.

FIG. 9A is a circuit diagram illustrating an example of a conventional capacitively coupled MOS type ESD protection circuit.

FIG. 9B is a graph illustrating an example of a current-voltage characteristic (by rise time of surge voltage) of a conventional capacitively coupled MOS type ESD protection circuit.

### DESCRIPTION OF THE EMBODIMENTS

The present invention is based on the following knowledge. That is, even if a gate, instead of being connected to a low potential terminal such as a ground potential as in a conventional GG-MOS type ESD protection circuit, is connected to a high potential terminal where static electricity is discharged, an internal circuit can still be protected.

Accordingly, in one embodiment of the present invention, layout area can be reduced compared to a conventional diode type ESD protection circuit, leakage current can be reduced compared to a GG-MOS type ESD protection circuit, and a malfunction which may occur in a capacitively coupled MOS type ESD protection circuit can be prevented.

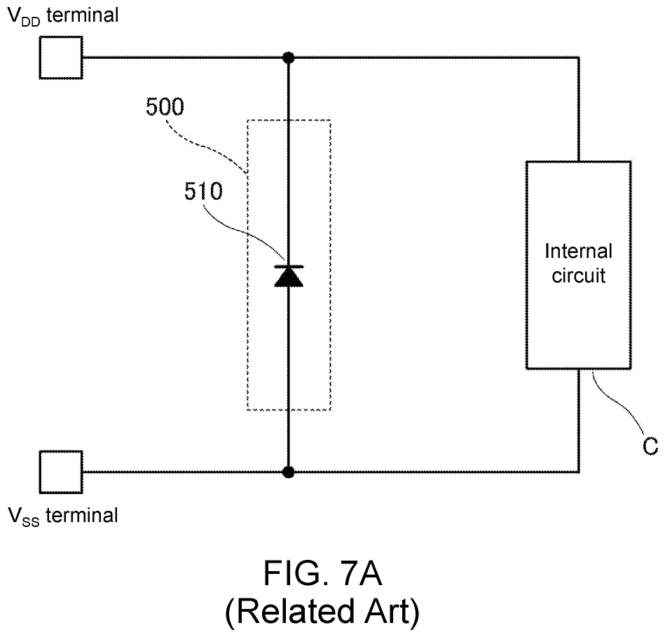

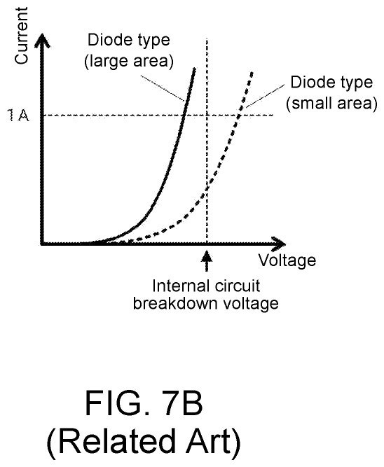

First, as the related art, a diode type ESD protection circuit, a GG-MOS type ESD protection circuit and a capacitively coupled MOS type ESD protection circuit will be described with reference to FIG. 7A to FIG. 9B.

In the following, a voltage and a current due to electrostatic discharge may be simply referred to as a “surge voltage” and a “surge current.”

FIG. 7A is a circuit diagram illustrating an example of a conventional diode type ESD protection circuit.

As illustrated in FIG. 7A, a diode type ESD protection circuit 500 is a circuit in which a diode 510 is connected between a V_{DD} terminal and a V_{SS} terminal. When a surge voltage is applied to the V_{DD} terminal, the diode type ESD protection circuit 500 protects an internal circuit C from electrostatic discharge by using the breakdown phenomenon and allowing a surge current to flow through the diode 510.

Since a withstand voltage of the diode 510 can be adjusted by adjusting an impurity concentration of a PN junction, the diode 510 is likely to cope with operating voltages of various semiconductor integrated circuits. The diode 510 has a simple structure and thus has little variation in characteristics. In addition, since no insulating film is used, there is no damage of insulating film.

FIG. 7B is a graph illustrating an example of a current-voltage characteristic (by diode junction area) of a conventional diode type ESD protection circuit. In this graph, the horizontal axis indicates the voltage of the V_{DD} terminal, and the vertical axis indicates the surge current flowing through the diode type ESD protection circuit. The solid line indicates a current-voltage characteristic of a diode having large junction area, and the dotted line indicates a current-voltage characteristic of a diode having small junction area.

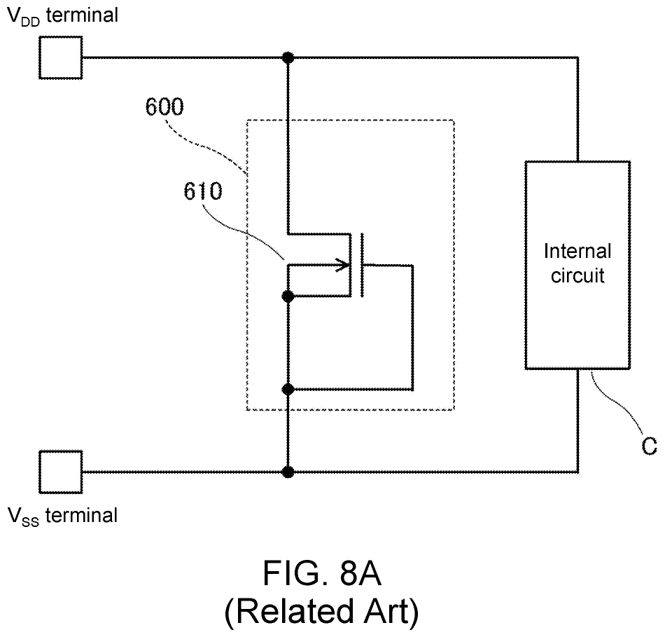

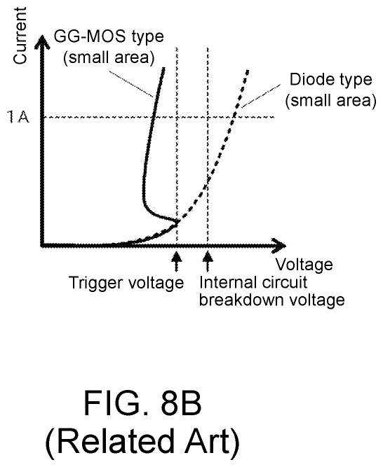

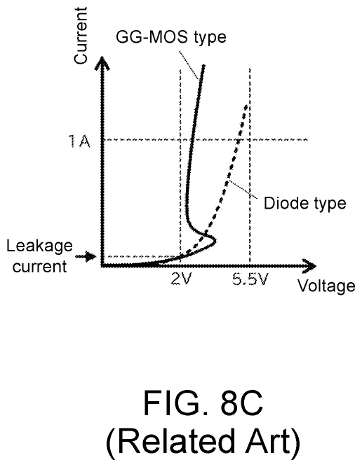

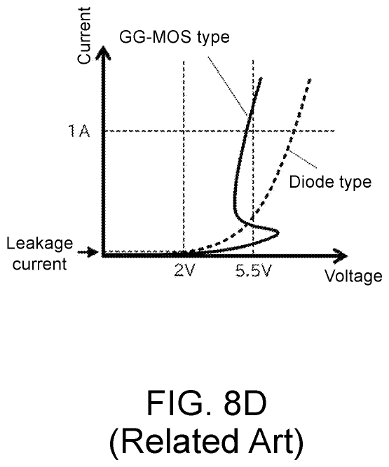

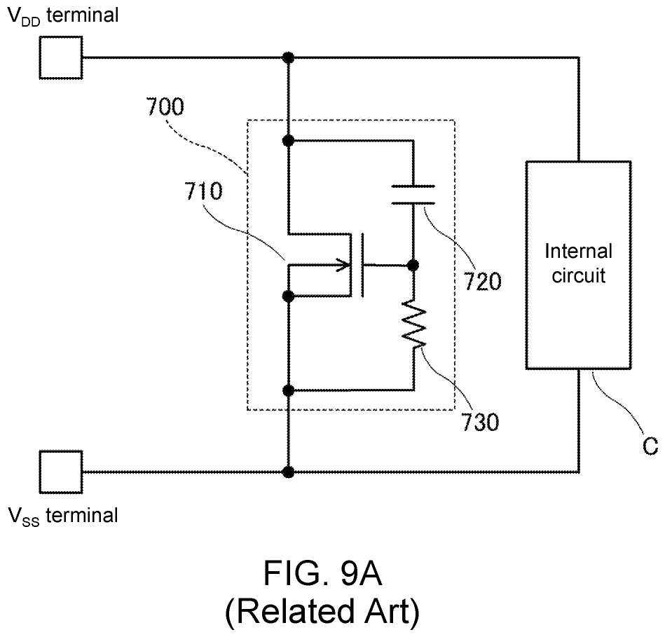

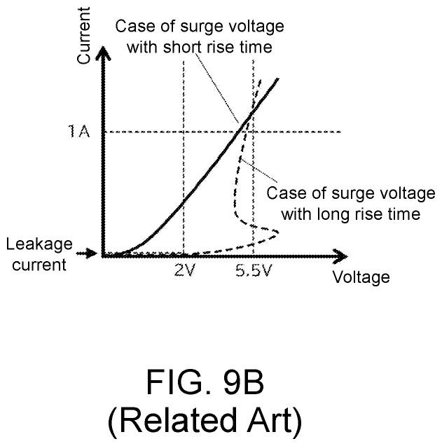

In not only the graph of FIG. 7B but also the graphs of FIG. 8B, FIG. 8C, FIG. 8D and FIG. 9B, a case where 2000 V of static electricity charged to the human body is applied to the V_{DD} terminal, namely a so-called 2000 V human body model (HBM), is assumed. To prevent an internal circuit from being damaged by the 2000 V HBM, it is necessary for an ESD protection circuit connected in parallel with the internal circuit to allow a surge current of approximately 1 ampere to flow to the V_{SS} terminal before the surge current flows into the internal circuit.

In the current-voltage characteristic indicated by the dotted line in FIG. 7B, since the junction area of the diode is small and a resistance value of a parasitic resistance is large, a surge voltage may reach a breakdown voltage of the internal circuit before the surge current of 1 ampere flows to the V_{SS} terminal. On the other hand, in the current-voltage characteristic indicated by the solid line in FIG. 7B, since the junction area of the diode is large and the resistance value of the parasitic resistance is small, the surge current of 1 ampere is able to flow to the V_{SS} terminal before the surge voltage reaches the breakdown voltage of the internal circuit.

Thus, in order for the diode type ESD protection circuit to protect the internal circuit from the 2000 V HBM, the junction area of the diode must be increased, and the layout area in a semiconductor integrated circuit may be increased.

It is more advantageous to reduce the layout area in the semiconductor integrated circuit for a GG-MOS type ESD protection circuit using a snapback operation than for the diode type ESD protection circuit.

Next, a conventional GG-MOS type ESD protection circuit is described.

FIG. 8A is a circuit diagram illustrating an example of a conventional GG-MOS type ESD protection circuit.

As illustrated in FIG. 8A, a GG-MOS type ESD protection circuit 600 is a circuit in which each of a drain terminal and a source terminal of a MOS transistor 610 is connected to the V_{DD} terminal and the V_{SS} terminal, and a gate terminal of the MOS transistor 610 is connected with the V_{SS} terminal.

FIG. 8B is a graph of a comparison of a current-voltage characteristic between a conventional diode type ESD protection circuit and a conventional GG-MOS type ESD protection circuit. In this graph, the horizontal axis indicates the voltage of the V_{DD} terminal, and the vertical axis indicates the surge current flowing through each ESD protection circuit. The solid line indicates a current-voltage characteristic of the GG-MOS type ESD protection circuit having small layout area, and the dotted line indicates a current-voltage characteristic of the diode type ESD protection circuit having small layout area like that indicated by the dotted line in FIG. 7B. That is, in FIG. 8B, the layout area of the conventional GG-MOS type ESD protection circuit is the same as the layout area of the conventional diode type ESD protection circuit.

In the current-voltage characteristic of the GG-MOS type ESD protection circuit indicated by the solid line in FIG. 8B, when a surge voltage is applied, the voltage of the V_{DD} terminal reaches a trigger voltage after avalanche breakdown occurs in a parasitic diode in the MOS transistor 610. Here, the trigger voltage refers to a trigger voltage of a parasitic bipolar transistor, and is a voltage at which the parasitic bipolar transistor switches from off to on. By turning on the parasitic bipolar transistor, current paths for flowing from a drain to a source are increased compared to when the parasitic bipolar transistor is off. Thus, the same current is able to flow at a low drain voltage, and a phenomenon (snapback operation) is observed in which the voltage drops after reaching the trigger voltage as illustrated in FIG. 8B. By this snapback operation, in the conventional GG-MOS type ESD protection circuit, the surge current of 1 ampere is able to flow to the V_{SS} terminal before the surge voltage reaches the breakdown voltage of the internal circuit.

Since the leakage current or the breakdown voltage of the GG-MOS type ESD protection circuit may be affected by multiple parameters such as gate length of the MOS transistor, thickness of a gate insulating film, channel impurity concentration, and impurity concentration of a low concentration region in the vicinity of the drain, the GG-MOS type ESD protection circuit is more complex than the diode type. Nevertheless, in the GG-MOS type ESD protection circuit, fine adjustment of a desired characteristic is possible by adjusting the concentration of impurities implanted in the vicinity of a drain region.

However, if an operating voltage of the internal circuit is about 2 V, adjustment becomes difficult in the diode type or the GG-MOS type.

Generally, in an internal circuit with an operating voltage of about 2 V, it is necessary to lower a minimum operating voltage. In order to improve an on/off ratio of a MOS transistor used in the internal circuit, the thickness of a gate insulating film of the MOS transistor of the internal circuit is set to 4 nm to 5 nm. In the case where the gate insulating film is a thin silicon oxide film as described above, an intrinsic withstand voltage slightly exceeds 10 MV/cm. Thus, the intrinsic withstand voltage of the gate insulating film of the MOS transistor of the internal circuit is often about 5.5 V. Hence, in the ESD protection circuit, a protection operation must be performed at a V_{DD} terminal voltage within a range of 2 V to 5.5 V.

In the diode type ESD protection circuit or the GG-MOS type ESD protection circuit, if an attempt is made to keep the protection operation within the above range, leakage current at the operating voltage of 2 V may increase as illustrated in FIG. 8C. In contrast, if an attempt is made to suppress the above leakage current, as illustrated in FIG. 8D, the protection operation is not completed within the above range, the voltage may exceed 5.5 V before the surge current of 1 ampere flows, and the internal circuit may be damaged.

In this way, in the diode type ESD protection circuit or the GG-MOS type ESD protection circuit, when the operating voltage of the internal circuit approaches 2 V, the ESD protection function cannot be satisfied due to a trade-off relationship between the leakage current and a protection operation voltage (that is, off current and on voltage).

A solution that eliminates this trade-off is a capacitively coupled MOS type ESD protection circuit described below.

FIG. 9A is a circuit diagram illustrating an example of a conventional capacitively coupled MOS type ESD protection circuit. FIG. 9B is a graph illustrating an example of a current-voltage characteristic (by rise time of surge voltage) of a conventional capacitively coupled MOS type ESD protection circuit. In this graph, the horizontal axis indicates the voltage of the V_{DD} terminal, and the vertical axis indicates the surge current flowing through each ESD protection circuit. The solid line indicates a current-voltage characteristic of the capacitively coupled MOS type ESD protection circuit, and the dotted line indicates a current-voltage characteristic of the GG-MOS type ESD protection circuit similar to that indicated by the solid line in FIG. 8D.

As illustrated in FIG. 9A, a capacitively coupled MOS type ESD protection circuit 700 is similar to the GG-MOS type in that each of a drain terminal and a source terminal of a MOS transistor 710 is connected to the V_{DD} terminal and V_{SS} terminal, and is different from the GG-MOS type in that a gate is connected to the V_{DD} terminal via a capacitor 720 and also to the V_{SS} terminal via a resistive element 730. A threshold voltage of the MOS transistor 710 is set to 2 V or less.

In the capacitively coupled MOS type ESD protection circuit 700, if the surge voltage has a long rise time, a potential of the capacitively coupled gate is less likely to change, and no current flows through the capacitively coupled MOS type ESD protection circuit 700. That is, in this case, the capacitively coupled MOS type ESD protection circuit 700 achieves a current-voltage characteristic as indicated by the solid line in FIG. 9B without performing a protection operation within the range of 2 V to 5.5 V, and leakage current can be reduced. On the other hand, if the surge voltage has a short rise time, the potential of the capacitively coupled gate changes, the MOS transistor 710 with a threshold voltage set to 2 V or less performs a protection operation by allowing a current to flow through a channel, and the surge current is discharged.

In this way, in the capacitively coupled MOS type ESD protection circuit 700, by the characteristic of switching between on and off by capacitive coupling, the trade-off in the diode type ESD protection circuit or the GG-MOS type ESD protection circuit is eliminated.

However, when the capacitively coupled MOS type ESD protection circuit is used for a terminal which receives or outputs a signal with a short rise time equivalent to electrostatic discharge and operates, a malfunction may occur. Thus, the capacitively coupled MOS type ESD protection circuit can only be used for limited terminals.

In the capacitively coupled MOS type ESD protection circuit, since a high voltage is applied to the gate during operation, the avalanche breakdown which causes an operation of a parasitic bipolar transistor is less likely to occur. Hence, as indicated by the solid line in FIG. 9B, the current-voltage characteristic of the capacitively coupled MOS type ESD protection circuit becomes like the current-voltage characteristic of the diode type ESD protection circuit indicated by the dotted line in FIG. 7B. When it is attempted to allow a large current to flow through, the layout area must be increased as indicated by the solid line in FIG. 7B.

An ESD protection circuit in one embodiment of the present invention is connected in parallel with a protected circuit which operates at a predetermined operating voltage between a first terminal and a second terminal, and includes an NMOS transistor. At least a drain of the NMOS transistor is connected to the first terminal, and a source of the NMOS transistor is connected to the second terminal. A threshold voltage, an avalanche breakdown voltage of a parasitic diode, and a trigger voltage of a parasitic bipolar transistor of the NMOS transistor are higher than the operating voltage of the protected circuit and lower than a breakdown voltage of the protected circuit and a breakdown voltage of a gate insulating film of the NMOS transistor.

Accordingly, the ESD protection circuit can be reduced in layout area compared to the conventional diode type or capacitively coupled MOS type ESD protection circuit and can be reduced in leakage current compared to the diode type or GG-MOS type ESD protection circuit. In the ESD protection circuit, a malfunction like that in the capacitively coupled MOS type ESD protection circuit does not occur. The ESD protection circuit can be used for a terminal that receives and outputs a voltage with a short rise time.

The predetermined operating voltage is a predetermined voltage at which the protected circuit is able to operate, and is in a range from a minimum operating voltage to a maximum operating voltage of the protected circuit.

Embodiments of the present invention are described below in detail with reference to the drawings.

In the drawings, the same components may be denoted by the same reference numerals, and repeated description may be omitted.

In the drawings, an X direction, a Y direction, and a Z direction are orthogonal to each other. Directions including the X direction and a direction (−X direction) opposite to the X direction are referred to as “X-axis direction,” directions including the Y direction and a direction (−Y direction) opposite to the Y direction are referred to as “Y-axis direction”, directions including the Z direction and a direction (−Z direction) opposite to the Z direction are referred to as “Z-axis direction” (height direction, thickness direction). In this respect, in each of the following embodiments, a surface of each film on the Z-direction side may be referred to as a “surface.”

The drawings are schematic, and width, length and depth ratios are not as illustrated in the drawings.

### First Embodiment

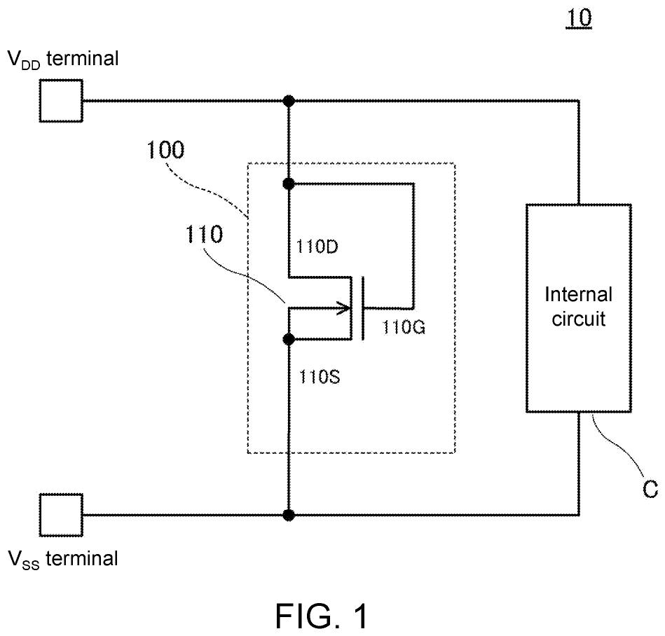

FIG. 1 is a circuit diagram illustrating an ESD protection circuit and a semiconductor device in a first embodiment of the present invention.

As illustrated in FIG. 1, in a semiconductor device 10, an internal circuit C is connected between a V_{DD} terminal as a first terminal and a V_{SS} terminal as a second terminal.

The internal circuit C operates at an operating voltage applied between the V_{DD} terminal and the V_{SS} terminal having a ground potential.

An ESD protection circuit 100 is connected in parallel with the internal circuit C being a protected circuit to be protected from damage caused by electrostatic discharge.

The ESD protection circuit 100 is an N-channel MOS (NMOS) transistor 110 in which a drain 110D and a gate 110G are electrically connected to the V_{DD} terminal, and a source 110S is electrically connected to the V_{SS} terminal.

The operating voltage of the internal circuit C varies depending on the purpose. The operating voltage is set to 2 V in the first embodiment, and 2 V is applied to the V_{DD} terminal.

Generally, if an operating voltage of an internal circuit is 2V, an intrinsic breakdown voltage of a gate insulating film of a MOS transistor included in the internal circuit is about 5.5 V. Hence, if there is no ESD protection circuit, in the case where static electricity is discharged to the V_{DD} terminal, a voltage of 5.5 V or more may be applied to and may damage the gate insulating film of the MOS transistor included in the internal circuit.

That is, it suffices if the ESD protection circuit 100 performs a protection operation before the voltage of the V_{DD} terminal reaches 5.5 V or more, and does not perform the protection operation if 2 V being the operating voltage of the internal circuit C is applied to the V_{DD} terminal. A film thickness of a gate insulating film of the NMOS transistor 110 may be set so that an intrinsic withstand voltage of the gate insulating film also becomes 5.5 V.

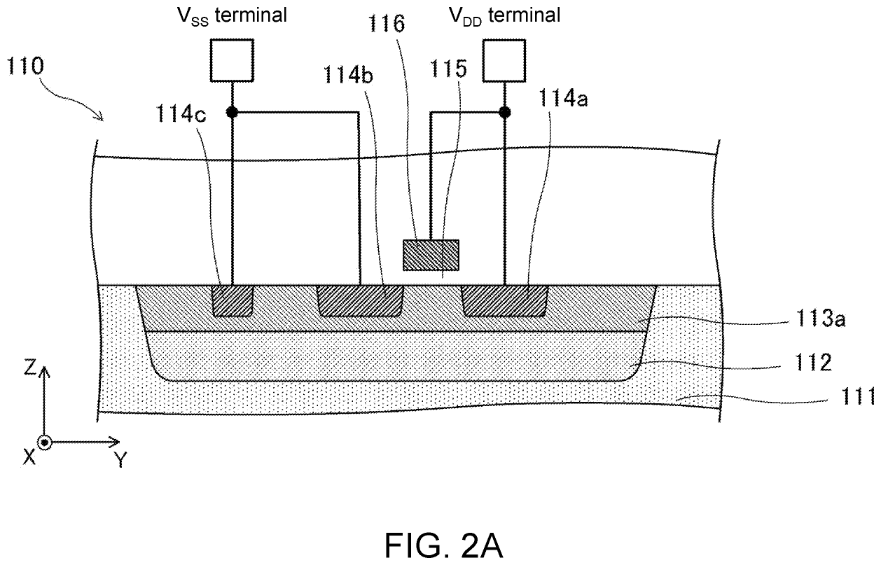

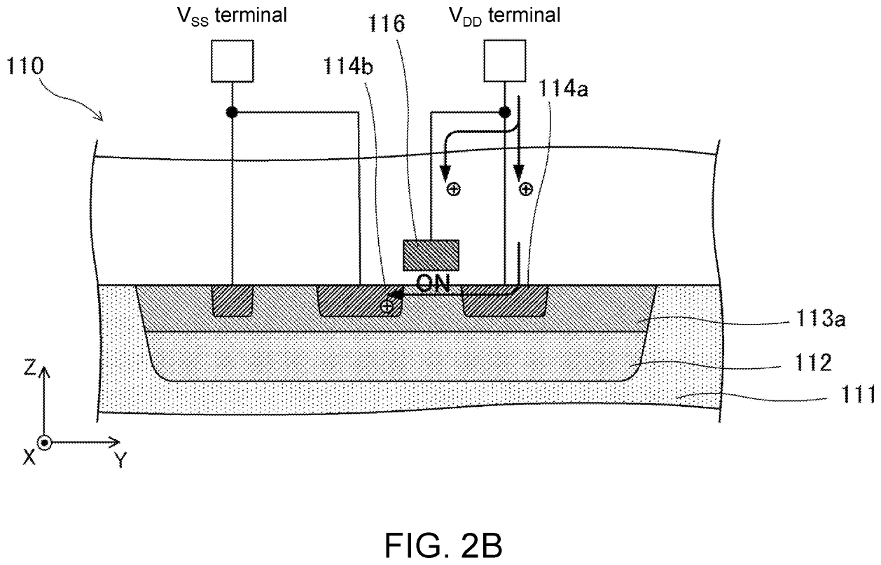

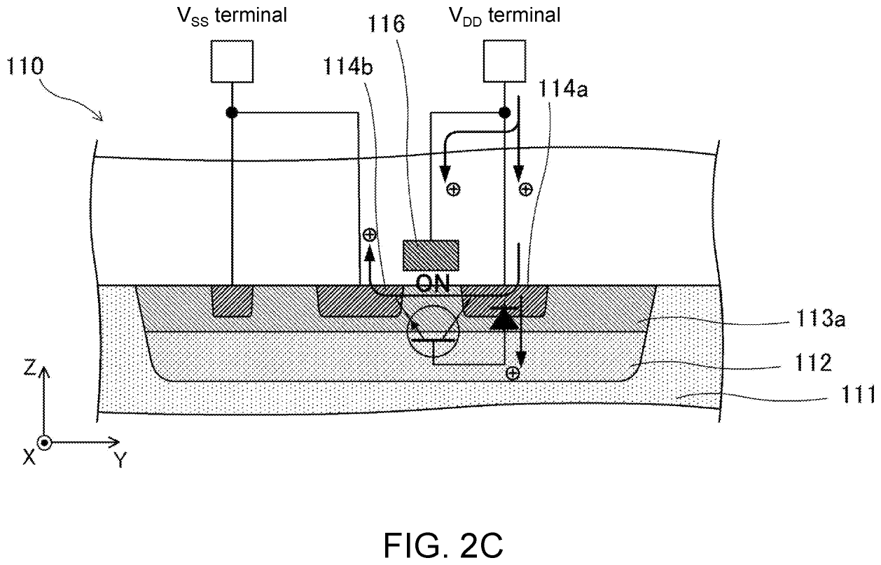

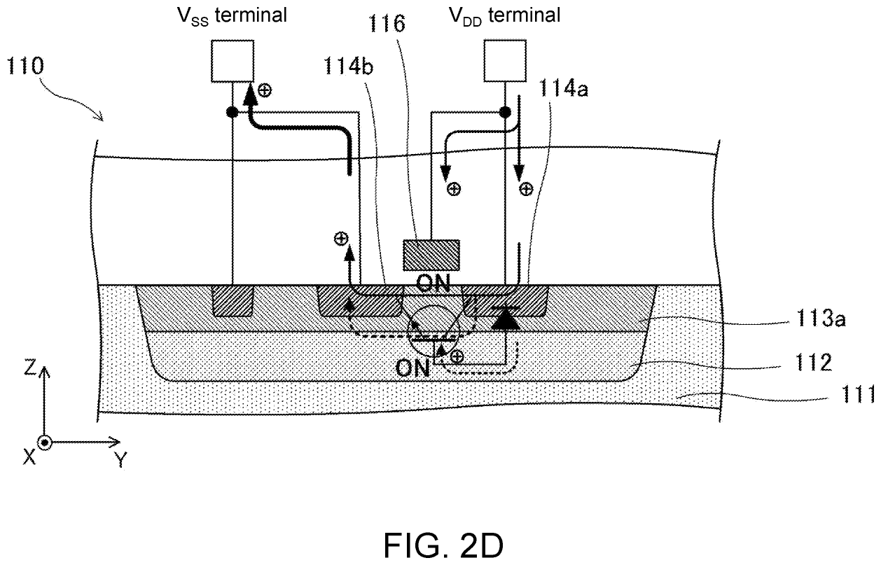

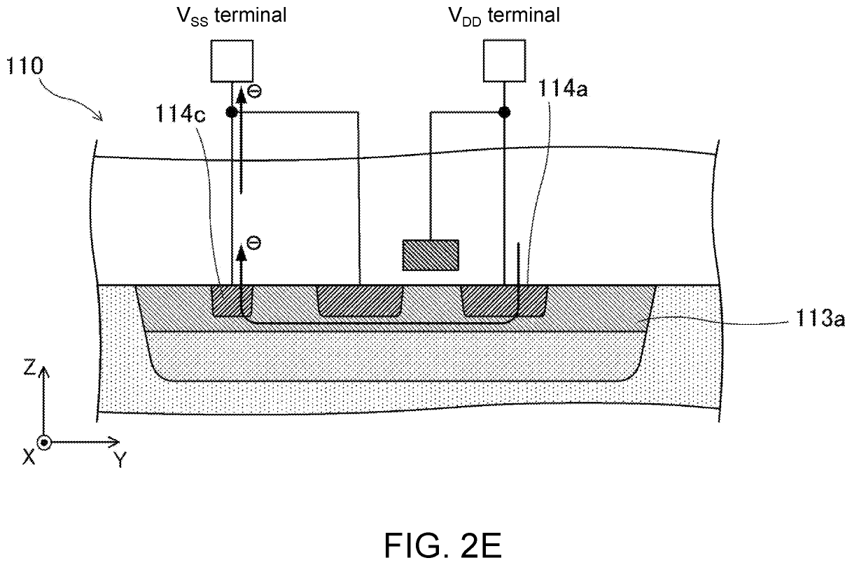

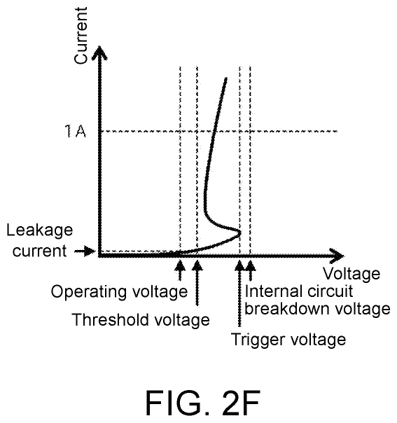

FIG. 2A is a schematic sectional view illustrating an example of a structure of an NMOS transistor in the first embodiment.

As illustrated in FIG. 2A, the NMOS transistor 110 has a structure in which a P type well region 112 being a P type low concentration region is formed on a semiconductor substrate 111, and a P type intermediate concentration region 113a is formed on the P type well region 112.

In the first embodiment, the P type intermediate concentration region 113a is formed on the P type well region 112. However, the present invention is not limited thereto. The P type well region 112 of low concentration may be set to be of intermediate concentration instead of forming the P type intermediate concentration region 113a.

A gate insulating film 115 is laminated on an upper surface of the P type intermediate concentration region 113a, and a gate electrode 116 is further laminated on the gate insulating film 115.

In an upper part of the P type intermediate concentration region 113a, an N type high concentration drain region 114a and an N type high concentration source region 114b are formed so as to sandwich the gate electrode 116 in plan view. In this way, the P type intermediate concentration region 113a is also provided in a channel region between the N type high concentration drain region 114a and the N type high concentration source region 114b. In the upper part of the P type intermediate concentration region 113a, a well electrode 114c is formed as a P type high concentration region in a position spaced apart from the N type high concentration source region 114b.

In the first embodiment, the N type high concentration source region 114b and the well electrode 114c are spaced apart. However, the present invention is not limited thereto. The N type high concentration source region 114b and the well electrode 114c may be brought into contact like butting contact.

The N type high concentration drain region 114a and the gate electrode 116 are connected to the V_{DD} terminal, and the N type high concentration source region 114b and the well electrode 114c are connected to the V_{SS} terminal.

Generally, a well region of an ESD protection circuit is often formed simultaneously with a well region of an internal circuit in the same process. Thus, the formation of the P type intermediate concentration region 113a in addition to the P type well region 112 being a well region as in the first embodiment is not necessarily common.

By adjusting an impurity concentration of the P type intermediate concentration region 113a, the threshold voltage, the avalanche breakdown voltage of the parasitic diode, and the trigger voltage of the parasitic bipolar transistor of the NMOS transistor 110 are adjustable.

As described above, it is necessary for the ESD protection circuit 100 to perform a protection operation before the voltage of the V_{DD} terminal reaches 5.5 V or more, and not to perform the protection operation if 2 V being the operating voltage of the internal circuit C is applied to the V_{DD} terminal. Hence, by adjusting the impurity concentration of the P type intermediate concentration region 113a, the threshold voltage, the avalanche breakdown voltage of the parasitic diode, and the trigger voltage of the parasitic bipolar transistor of the NMOS transistor 110 are adjusted to 2 V or more and 5.5 V or less.

Here, the principle of operation in the case where positive static electricity flows into the V_{DD} terminal of an IC in which the internal circuit C has an operating voltage of 2 V is described.

When the threshold voltage of the NMOS transistor 110 is adjusted to, for example, 2.2 V, if 2 V is applied as the operating voltage to the V_{DD} terminal, since the ESD protection circuit 100 performs no protection operation, the internal circuit C operates normally. On the other hand, if a surge voltage of 2.2 V or more is applied to the V_{DD} terminal, as illustrated in FIG. 2B, the NMOS transistor 110 changes to an ON state, and a surge current flows from the N type high concentration drain region 114a to the N type high concentration source region 114b through the channel region.

In this way, the impurity concentration of the P type intermediate concentration region 113a is adjusted, and the threshold voltage is higher than the operating voltage and lower than the breakdown voltage of the internal circuit C and the breakdown voltage of the gate insulating film 115 of the NMOS transistor 110. Accordingly, the NMOS transistor 110 is turned on when the surge voltage is applied, and the internal circuit C is protected without damaging the NMOS transistor 110 (protection operation 1).

However, with only the protection operation 1, the same current-voltage characteristic as that in a “case of input voltage with a short rise time” indicated by the solid line in FIG. 9B is achieved, and when the ESD protection circuit has small area, it becomes unlikely to protect the internal circuit C. In order to protect the internal circuit C, a gate width of the gate electrode 116 must be increased to allow a relatively large surge current to flow. As a result, the layout area of the ESD protection circuit is increased, and leakage current is also increased.

In the case of the conventional GG-MOS type ESD protection circuit, since the gate electrode is connected to the V_{SS} terminal, an electric field in the vicinity of a semiconductor surface between the gate and the drain becomes strong, causing surface breakdown, and a thus generated carrier induces an operation of a parasitic bipolar transistor. On the other hand, in the first embodiment, the gate electrode is connected to a drain electrode. Hence, although the operation of the parasitic bipolar transistor due to surface breakdown as in the GG-MOS type ESD protection circuit cannot be expected, by providing the P type intermediate concentration region 113a, avalanche breakdown is caused in a parasitic diode formed by a junction of the P type intermediate concentration region 113a and the N type high concentration drain region 114a. Thus, the operation of the parasitic bipolar transistor can be induced.

The avalanche breakdown voltage of the parasitic diode and the trigger voltage of the parasitic bipolar transistor whose operation is induced thereby are adjusted by the impurity concentration of the P type intermediate concentration region 113a, like the threshold voltage.

Like the threshold voltage, the avalanche breakdown voltage of the parasitic diode is adjusted to 2 V or more so that leakage current of a desired value or less is achieved when the operating voltage of 2 V of the internal circuit C is applied to the V_{DD} terminal. The trigger voltage of the parasitic bipolar transistor whose operation is induced thereby naturally exceeds 2 V. In order to protect the internal circuit C from an ESD surge applied from the V_{DD} terminal, the trigger voltage of the parasitic bipolar transistor is adjusted to 5.5 V or less. At this time, if the trigger voltage of the parasitic bipolar transistor exceeds 5.5 V when the avalanche breakdown voltage of the parasitic diode is set to 2 V or more, a gate length of the NMOS transistor 110 is reduced and only the trigger voltage of the parasitic bipolar transistor is adjusted down. Since the gate electrode is not connected to the V_{SS} terminal as in the GG-MOS type ESD protection circuit, it is easier to lower the trigger voltage of the operation of the parasitic bipolar transistor than in the GG-MOS type ESD protection circuit, and it is easy to protect the internal circuit.

By the operation of the parasitic bipolar transistor, apart from the surge current which flows from the N type high concentration drain region 114a to the N type high concentration source region 114b through the channel region as the protection operation 1, a relatively large amount of surge current is able to flow through a parasitic bipolar region of a portion deeper than (−Z direction) the channel region, as illustrated in FIG. 2C and FIG. 2D (protection operation 2).

That is, there are two paths for flowing the surge current, namely, a current path (protection operation 1) flowing in the channel region and a current path (protection operation 2) flowing in the parasitic bipolar region in the portion deeper than (−Z direction) the channel region. Hence, the ESD protection circuit 100 may have a smaller area than the GG-MOS type ESD protection circuit which is favorable in terms of area among the related art.

In the structure of the NMOS transistor 110, since the channel region is the P type intermediate concentration region 113a, it may be limited to a case where the threshold voltage and the breakdown voltage of the parasitic diode can be adjusted to desired values at once by adjusting the impurity concentration of the P type intermediate concentration region 113a.

Next, a case is described where static electricity of a negative charge is discharged to the V_{DD} terminal.

As illustrated in FIG. 2E, a negative charge flows forward in the parasitic diode between the N type high concentration drain region 114a and the P type well region 112, and then flows from the P type well region 112 to the V_{SS} terminal through the well electrode 114c being a P type high concentration region. Since there is no place where a high electric field is applied in the above path, no damage is caused.

Accordingly, the ESD protection circuit 100 is able to protect the internal circuit C by flowing the negative charge to the V_{SS} terminal by the structure of the NMOS transistor 110.

A method for forming the NMOS transistor 110 can be realized, for example, as follows. First, the P type well region 112 is formed on the semiconductor substrate 111, and the gate insulating film 115 and the gate electrode 116 are formed thereon. Then, P type impurities are implanted into the entire surface of the semiconductor substrate 111 so as to penetrate the gate insulating film 115 and the gate electrode 116, and the P type intermediate concentration region 113a is formed. Then, N type impurities are implanted at a high concentration, and the N type high concentration drain region 114a and the N type high concentration source region 114b are formed.

The P type intermediate concentration region 113a may be formed before formation of the gate insulating film 115 and the gate electrode 116.

In this way, the ESD protection circuit 100 is connected in parallel with the internal circuit C which operates at a predetermined operating voltage between the V_{DD} terminal and the V_{SS} terminal, and includes the NMOS transistor 110. In the NMOS transistor 110, the N type high concentration drain region 114a and the gate electrode 116 are connected to the V_{DD} terminal, and the N type high concentration source region 114b is connected to the V_{SS} terminal. As illustrated in FIG. 2F, in the NMOS transistor 110, the threshold voltage, a Zener breakdown voltage of the parasitic diode, and the trigger voltage of the parasitic bipolar transistor are higher than the operating voltage of the internal circuit C and lower than the breakdown voltage of the internal circuit C and the breakdown voltage of the gate insulating film 115 of the NMOS transistor 110.

Accordingly, the ESD protection circuit 100 can be reduced in layout area and can be reduced in leakage current, and a malfunction which may occur in the capacitively coupled MOS type ESD protection circuit can be prevented.

In the case of the embodiments illustrated in FIG. 1 and FIG. 2A to FIG. 2F, the gate 110G of the NMOS transistor 110 is directly connected to the V_{DD} terminal. Hence, due to sudden inflow of the surge current, the potential of the gate 110G may exceed a withstand voltage of the gate insulating film of the NMOS transistor 110 before the protection operation 1 and the protection operation 2 are sufficiently performed, and the gate insulating film may be damaged. In that case, it is possible to avoid damage by Modification 1 illustrated below.

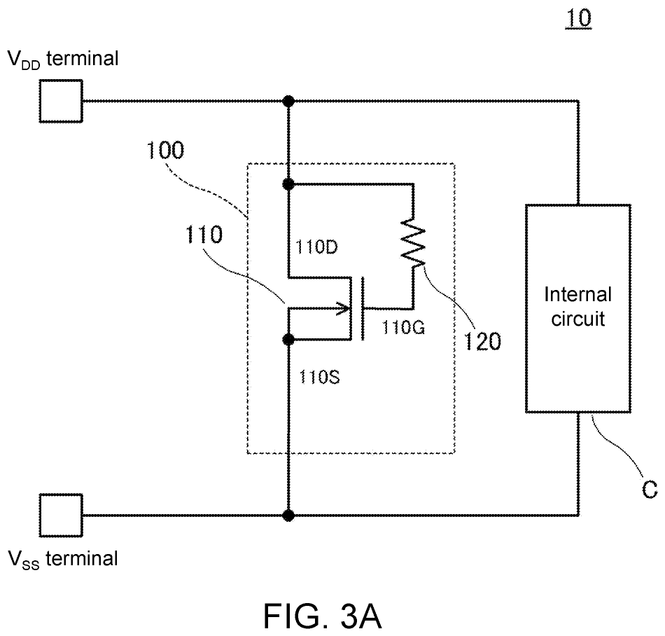

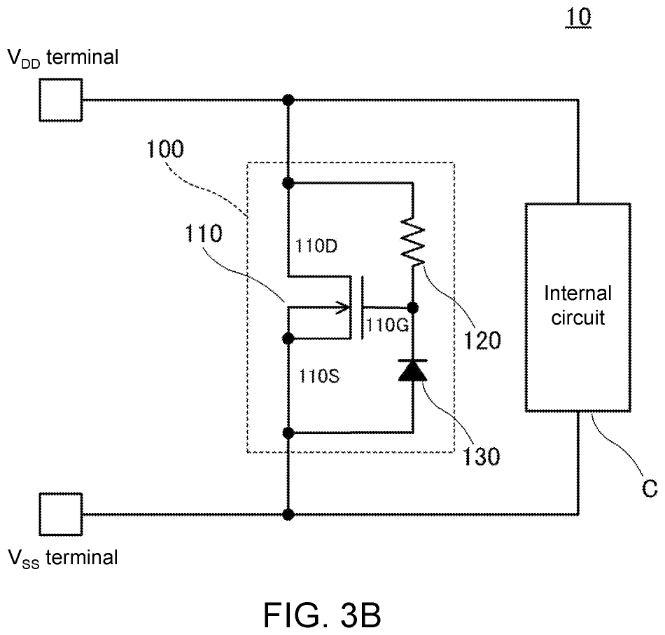

A diagram of an ESD protection circuit of Modification 1 of the first embodiment is illustrated in FIG. 3A.

As illustrated in FIG. 3A, the ESD protection circuit 100 in Modification 1 is the same as the ESD protection circuit 100 of FIG. 1 except that a resistive element 120 is connected between the gate 110G and the drain 110D of the NMOS transistor 110 in the ESD protection circuit 100 illustrated in FIG. 1.

In Modification 1, by connecting the resistive element 120 between the gate 110G and the drain 110D, a sharp rise in voltage at the gate 110G of the NMOS transistor 110 when static electricity flows into the V_{DD} terminal can be dulled. Hence, the protection operation 1 and the protection operation 2 can be performed before the voltage of the gate 110G exceeds the withstand voltage of the gate insulating film of the NMOS transistor 110, and static electricity charges accumulated at the drain 110D can be released to the source 110S before flowing into the gate 110G, thereby preventing damage to the gate insulating film.

A resistance value of the resistive element 120 is preferably several kΩ to several tens of kΩ.

In FIG. 1, FIG. 2A to FIG. 2F, and FIG. 3A, in the case of a charged device model (CDM) in which the entire IC is charged, unlike the HBM, charges may remain at the gate 110G of the NMOS transistor 110 and the gate insulating film may be damaged. In that case, it is possible to avoid damage by Modification 2 illustrated below.

A diagram of an ESD protection circuit of Modification 2 of the first embodiment is illustrated in FIG. 3B.

The ESD protection circuit 100 in Modification 2 is the same as the ESD protection circuit 100 in Modification 1 except that a diode 130 is connected between the gate 110G and the source 110S of the NMOS transistor 110 in Modification 1.

In Modification 2, since charges of the gate 110G can be released through the diode 130 connected between the gate 110G and the source 110S, damage to the gate insulating film of the NMOS transistor 110 can be prevented.

A withstand voltage of the diode 130 is set higher than the operating voltage of the internal circuit C in order to prevent the occurrence of leakage current during operation of the internal circuit C.

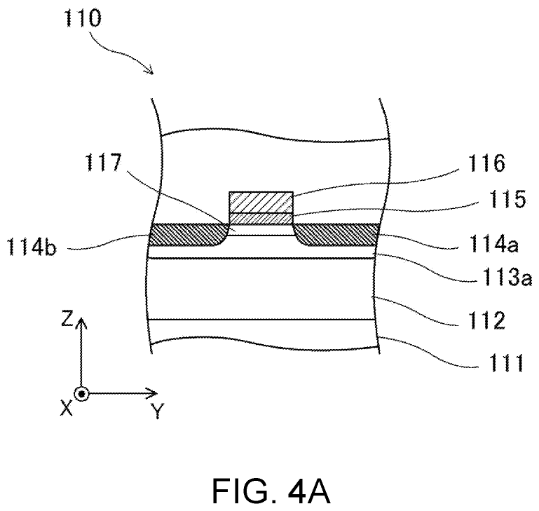

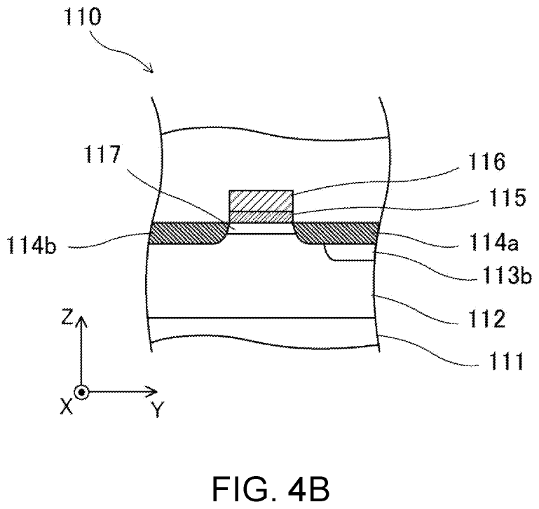

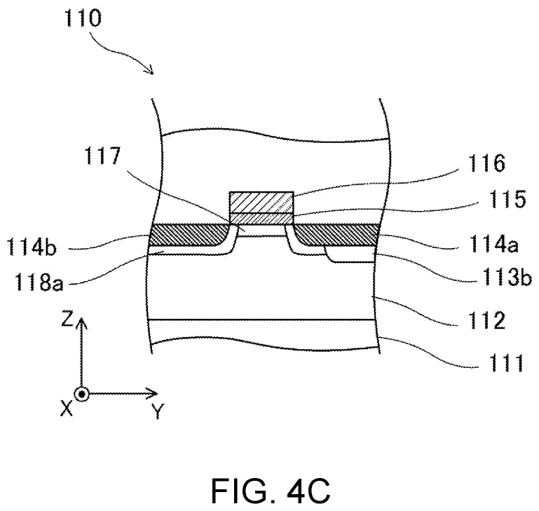

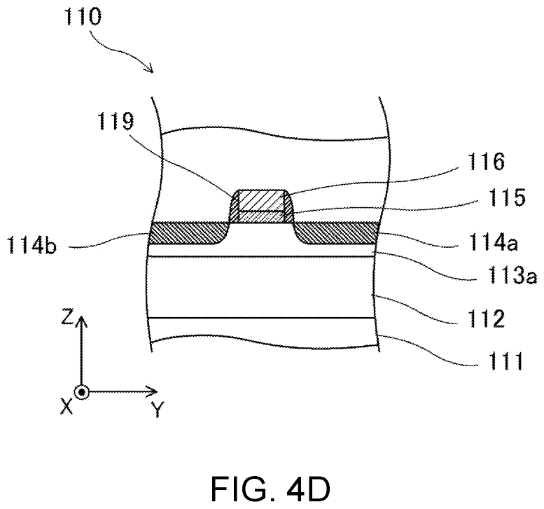

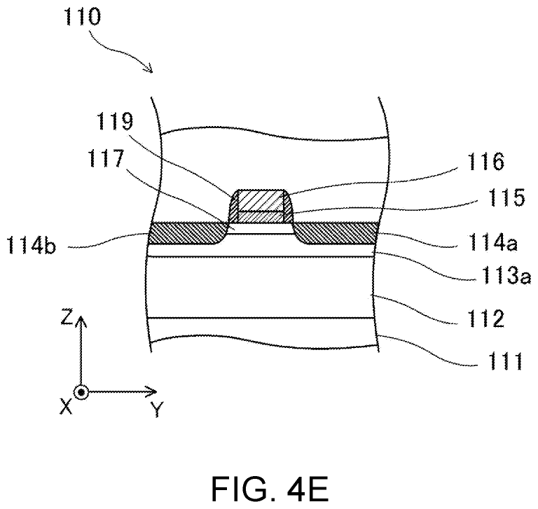

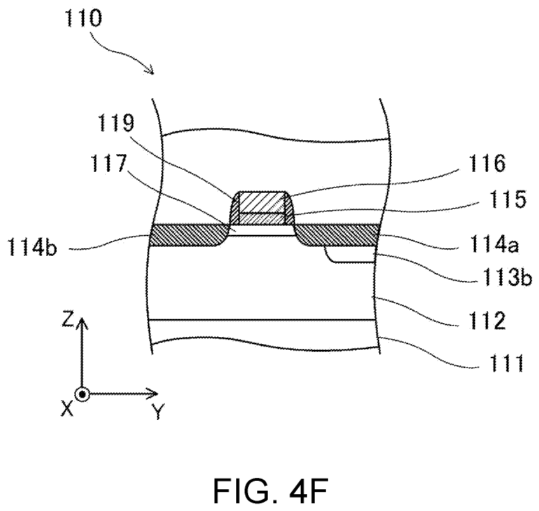

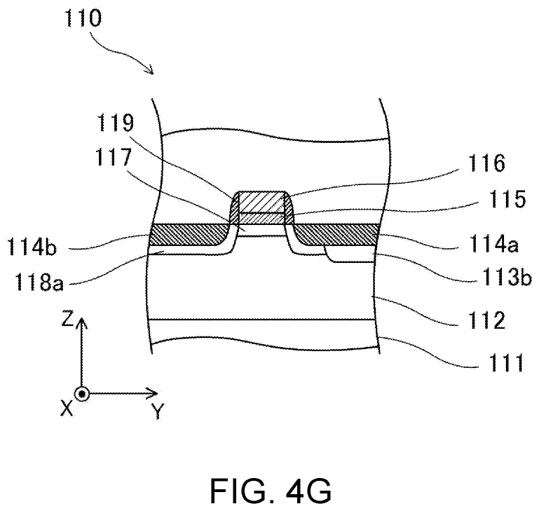

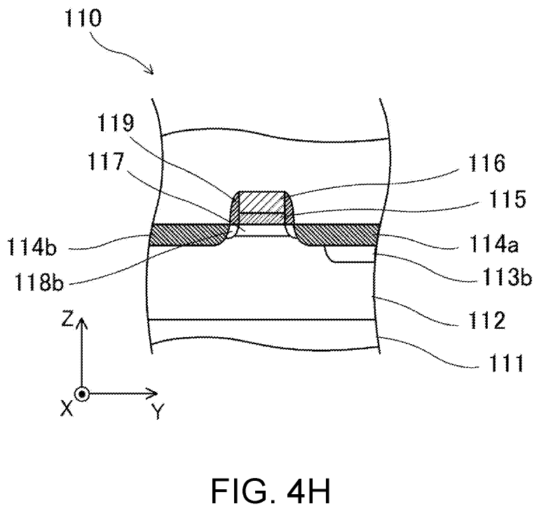

Next, other examples of structures of NMOS transistors other than the NMOS transistor 110 illustrated in FIG. 2A will be described with reference to FIG. 4A to FIG. 4H.

FIG. 4A to FIG. 4H are schematic sectional views illustrating the vicinity of the N type high concentration drain region 114a, the N type high concentration source region 114b and the gate electrode 116.

Any of the NMOS transistors illustrated in FIG. 2A and FIG. 4A to FIG. 4H may be used in the NMOS transistor of the ESD protection circuit illustrated in FIG. 1, FIG. 3A and FIG. 3B.

FIG. 4A illustrates the same structure as the NMOS transistor 110 illustrated in FIG. 2A except that a P type intermediate concentration channel region 117 is further formed in the NMOS transistor 110 illustrated in FIG. 2A.

By forming the P type intermediate concentration channel region 117, an impurity concentration of the P type intermediate concentration channel region 117 can be adjusted separately from the P type intermediate concentration region 113a. For example, in order to suppress leakage current when the operating voltage of the internal circuit C is applied to the V_{DD} terminal, the impurity concentration of the P type intermediate concentration region 113a is adjusted to the low concentration side and the avalanche breakdown voltage of the parasitic diode is increased. Under this influence, the threshold voltage is lowered, and the leakage current of the NMOS transistor 110 may not be able to be suppressed in the end. Even in such a case, the presence of the P type intermediate concentration channel region 117 makes it possible to independently adjust the impurity concentration of this region. Thus, the threshold voltage can be increased without changing the avalanche breakdown voltage of the parasitic diode of the NMOS transistor 110, and leakage current can be suppressed.

FIG. 4B illustrates the same structure as the NMOS transistor 110 illustrated in FIG. 4A except that a P type intermediate concentration region 113b instead of the P type intermediate concentration region 113a is formed directly under the N type high concentration drain region 114a in the NMOS transistor 110 illustrated in FIG. 4A.

By providing the structure of FIG. 4B, not only can the same effect as that of FIG. 4A be obtained, since a base region of a parasitic bipolar transistor directly underneath the P type intermediate concentration channel region 117 has a lower concentration than that of in FIG. 4A, the trigger voltage of the parasitic bipolar transistor is lowered, making it easier to protect the internal circuit C than in FIG. 4A.

FIG. 4C illustrates the same structure as the NMOS transistor 110 illustrated in FIG. 4B except that an N type low concentration region 118a is formed in the NMOS transistor 110 illustrated in FIG. 4B.

The N type low concentration region 118a has a so-called double diffused drain (DDD) structure. This DDD structure is generally a structure for improving a drain breakdown voltage of a MOS transistor, and this structure can also be applied to the present invention. By forming the N type low concentration region 118a, since the N type high concentration drain region 114a is substantially widened and heat is easily dispersed, electrostatic withstand voltage can be improved.

FIG. 4D to FIG. 4G respectively illustrate the same structures as the NMOS transistors illustrated in FIG. 2A and FIG. 4A to FIG. 4C except that a sidewall spacer 119 is provided on a sidewall of the gate insulating film 115 and the gate electrode 116 in the NMOS transistors illustrated in FIG. 2A and FIG. 4A to FIG. 4C. FIG. 4H illustrates the same structure as the NMOS transistor illustrated in FIG. 4G except that the N type low concentration region 118a is replaced by a shallowly formed N type low concentration region 118b in the NMOS transistor illustrated in FIG. 4G.

The sidewall spacer 119 is a technology used in a general semiconductor manufacturing process, and is formed by forming the gate insulating film 115 and the gate electrode 116 and then removing the insulating film formed on the entire surface by etchback. By utilizing FIG. 4D to FIG. 4H, the present invention can be applied to a manufacturing process using a sidewall spacer without an additional process.

Here, in FIG. 4D to FIG. 4F, no N type region is present directly under the sidewall spacer 119. In the cases of these structures, when a positive voltage is applied to the gate electrode 116, since a channel directly underneath the sidewall spacer 119 is difficult to invert, it is difficult for a channel current to flow, and this would be a problem when the structure is used as a normal MOS transistor. However, as described above, in the present invention, since the operation of the parasitic bipolar transistor is performed by avalanche breakdown between the N type high concentration drain region 114a and the P type intermediate concentration region 113b, and the gate is not grounded as in the GG-MOS type ESD protection circuit, a hole generated by the avalanche breakdown is also increased in the potential of the channel portion, and the channel current is able to flow in addition to a current generated by the parasitic bipolar transistor. Accordingly, the protection operation 1 and the protection operation 2 also work in these structures, and the internal circuit C can be protected. For the above reason that the channel under the sidewall spacer 119 is difficult to invert, leakage current can also be suppressed.

On the other hand, in FIG. 4G to FIG. 4H, an N type region is present directly under the sidewall spacer 119. These N type low concentration regions 118a and 118b have so-called a double diffused drain (DDD) structure and a lightly doped drain (LDD) structure.

The DDD structure and the LDD structure are generally structures for improving a drain breakdown voltage of a transistor, and these structures can also be applied to the present invention. By forming the N type low concentration region 118b, since the N type high concentration drain region 114a is substantially widened and heat is easily dispersed, electrostatic withstand voltage can be improved.

In this way, the ESD protection circuit 100 is connected in parallel with the internal circuit C which operates at a predetermined operating voltage between the V_{DD} terminal and the V_{SS} terminal, and includes the NMOS transistor 110. In the NMOS transistor 110, the N type high concentration drain region 114a and the gate electrode 116 are connected to the V_{DD} terminal, and the N type high concentration source region 114b is connected to the V_{SS} terminal. As illustrated in FIG. 2F, in the NMOS transistor 110, the threshold voltage, the Zener breakdown voltage of the parasitic diode, and the trigger voltage of the parasitic bipolar transistor are higher than the operating voltage of the internal circuit C and lower than the breakdown voltage of the internal circuit C.

Accordingly, the ESD protection circuit 100 can be reduced in layout area and can be reduced in leakage current, and a malfunction which may occur in the capacitively coupled MOS type ESD protection circuit can be prevented.

### Second Embodiment

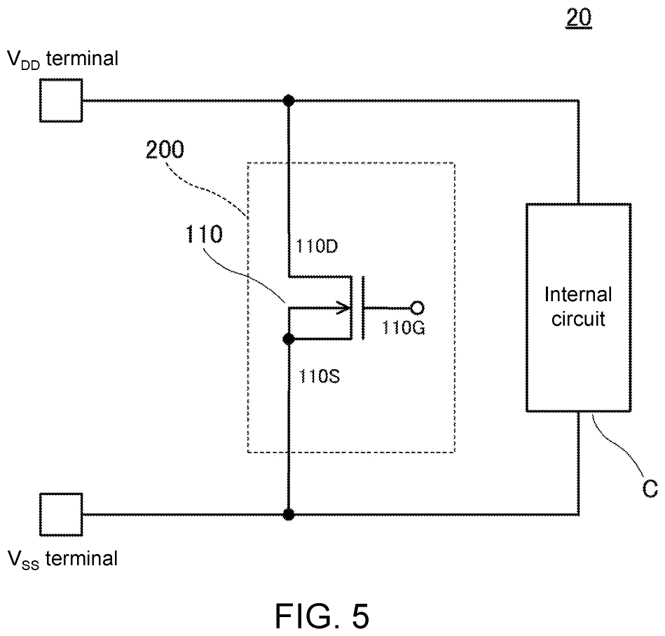

FIG. 5 is a circuit diagram illustrating an ESD protection circuit and a semiconductor device in a second embodiment of the present invention.

As illustrated in FIG. 5, an ESD protection circuit 200 in the second embodiment is the same as the first embodiment except that the gate 110G of the NMOS transistor 110 provided in the ESD protection circuit 100 of the first embodiment is not connected to the V_{DD} terminal and is in a floating state.

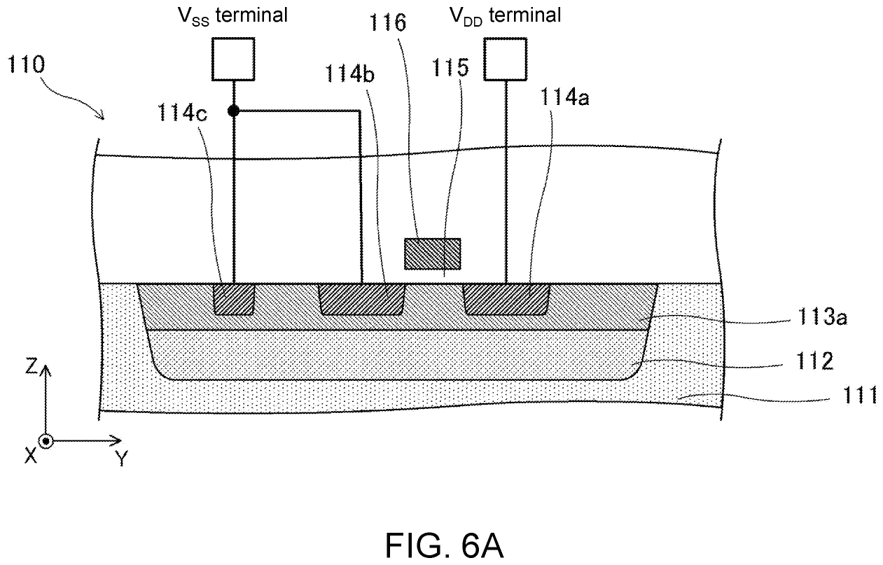

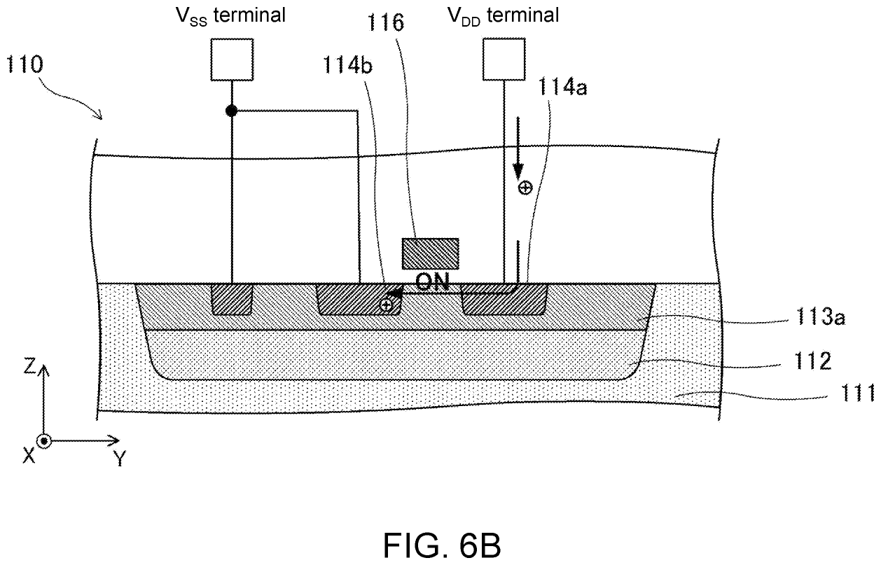

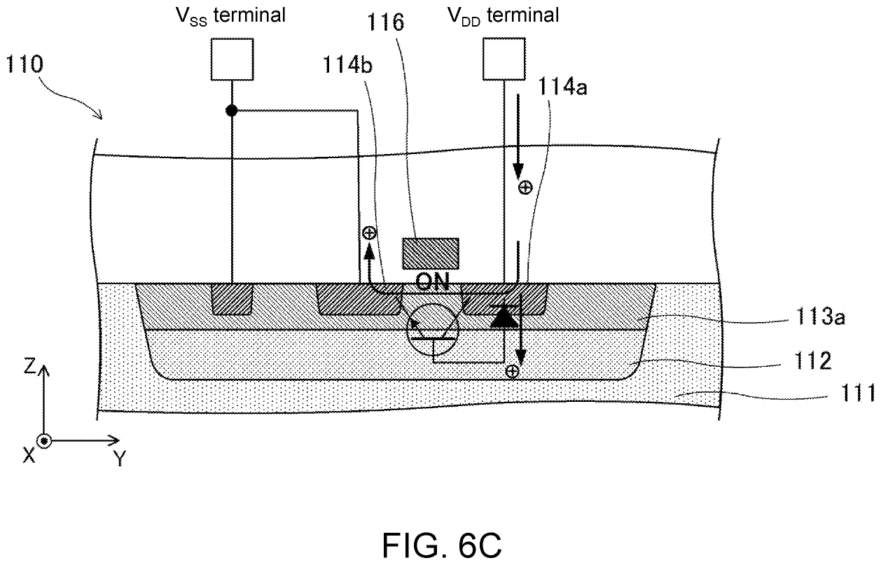

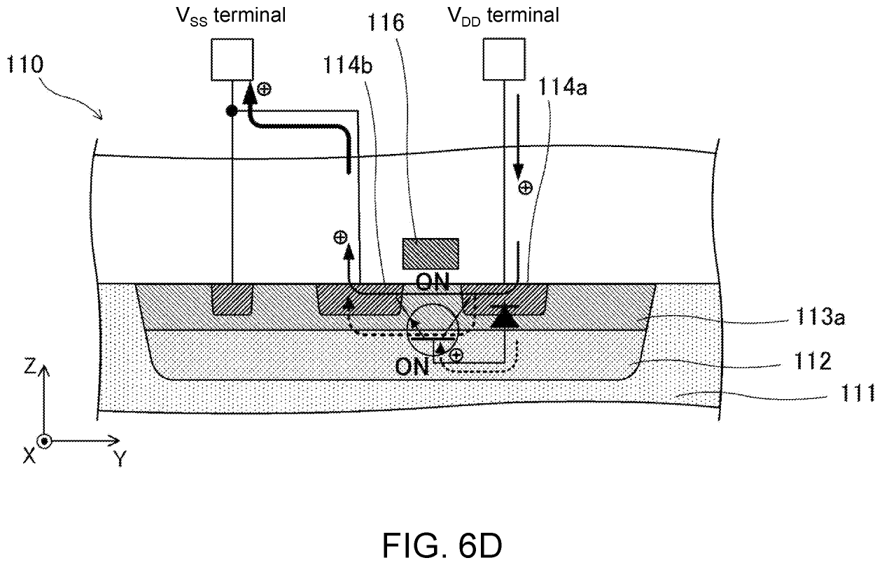

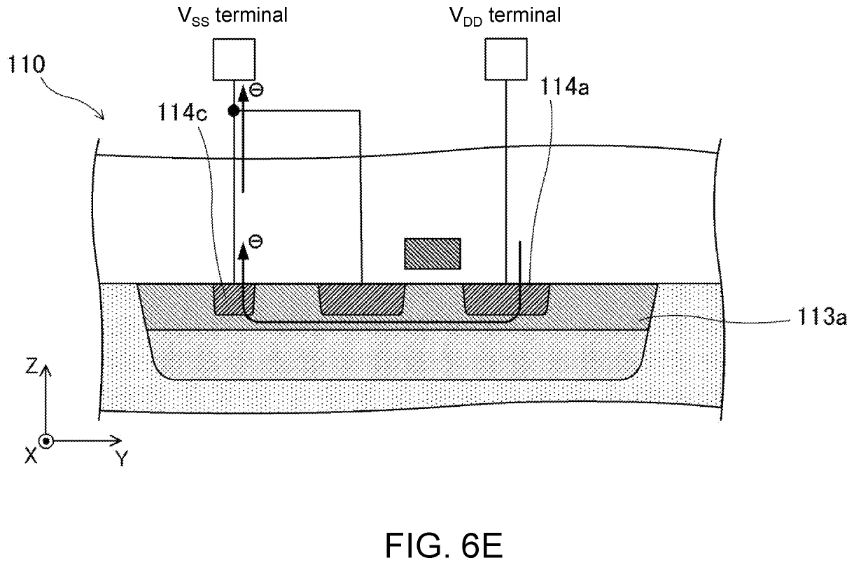

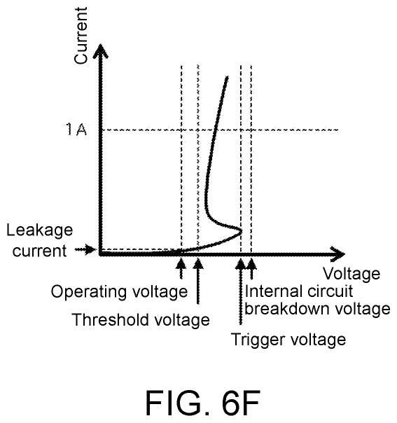

FIG. 6A is a schematic sectional view illustrating an example of a structure of an NMOS transistor in the second embodiment.

As illustrated in FIG. 6A, the gate electrode 116 in the second embodiment is in a floating state. If the gate electrode 116 is in a floating state, when positive static electricity flows into the V_{DD} terminal in an IC in which the internal circuit C has an operating voltage of 2 V, the principle of operation is as follows.

If the gate electrode 116 is in a floating state, when there is a voltage difference between the V_{DD} terminal and the V_{SS} terminal, a leakage current due to the punch-through phenomenon is likely to flow. Thus, it is necessary to prevent the punch-through phenomenon from occurring when a voltage equal to or less than the operating voltage of 2 V is applied to the V_{DD} terminal. In addition, an adjustment is necessary to cause the punch-through phenomenon to occur before 5.5 V, which is the breakdown voltage of the internal circuit C, is reached.

The adjustment is performed by adjusting the impurity concentration of the P type intermediate concentration region 113a, that is, adjusting the threshold voltage of the NMOS transistor 110. The punch-through current can be adjusted by extending the gate length of the NMOS transistor 110.

By the above adjustment, leakage current in the case where 2 V as the operating voltage is applied to the V_{DD} terminal is suppressed. If a surge voltage of 2 V or more is applied to the V_{DD} terminal, as illustrated in FIG. 6B, a surge current is caused to flow from the N type high concentration drain region 114a to the N type high concentration source region 114b through the channel region of the NMOS transistor 110 by the punch-through phenomenon (protection operation 1).

However, with only the protection operation 1, the same current-voltage characteristic as that in the “case of input voltage with a short rise time” indicated by the solid line in FIG. 9B is achieved, and when the ESD protection circuit has small area, it becomes unlikely to protect the internal circuit C. In order to protect the internal circuit C, the gate width of the gate electrode 116 must be increased to allow a relatively large surge current to flow. As a result, the layout area of the ESD protection circuit is increased, and leakage current is also increased.

On the other hand, in the second embodiment, as in the first embodiment, since avalanche breakdown is caused in the parasitic diode formed by the junction of the P type intermediate concentration region 113a and the N type high concentration drain region 114a, an operation of the parasitic bipolar transistor can be induced.

By the operation of the parasitic bipolar transistor, apart from the surge current which flows from the N type high concentration drain region 114a to the N type high concentration source region 114b through the channel region as the protection operation 1, a relatively large amount of surge current is able to flow through a parasitic bipolar region of a portion deeper than the channel region, as illustrated in FIG. 6C and FIG. 6D (protection operation 2).

Next, a case is described where static electricity of a negative charge is discharged to the V_{DD} terminal.

As illustrated in FIG. 6E, a negative charge flows forward in the parasitic diode between the N type high concentration drain region 114a and the P type well region 112, and then flows from the P type well region 112 to the V_{SS} terminal through the well electrode 114c being a P type high concentration region. Since there is no place where a high electric field is applied in the above path, no damage is caused.

Accordingly, the ESD protection circuit 200 is able to protect the internal circuit C by flowing the negative charge to the V_{SS} terminal by the structure of the NMOS transistor 110.

In this way, the ESD protection circuit 200 is connected in parallel with the internal circuit C which operates at a predetermined operating voltage between the V_{DD} terminal and the V_{SS} terminal, and includes the NMOS transistor 110. In the NMOS transistor 110, the N type high concentration drain region 114a is connected to the V_{DD} terminal, and the N type high concentration source region 114b is connected to the V_{SS} terminal. As illustrated in FIG. 6F, in the NMOS transistor 110, the threshold voltage, the Zener breakdown voltage of the parasitic diode, and the trigger voltage of the parasitic bipolar transistor are higher than the operating voltage of the internal circuit C and lower than the breakdown voltage of the internal circuit C.

Accordingly, the ESD protection circuit 200 can be reduced in layout area and can be reduced in leakage current, and a malfunction which may occur in the capacitively coupled MOS type ESD protection circuit can be prevented.

As described above, an ESD protection circuit in one embodiment of the present invention is connected in parallel with a protected circuit which operates at a predetermined operating voltage between a first terminal and a second terminal, and includes an NMOS transistor. In the NMOS transistor, at least a drain is connected to the first terminal, and a source is connected to the second terminal. The threshold voltage and the trigger voltage of the parasitic bipolar transistor are higher than the operating voltage and lower than the breakdown voltage of the protected circuit and the breakdown voltage of the gate insulating film of the NMOS transistor of the ESD protection circuit.

Accordingly, the ESD protection circuit can be reduced in layout area and can be reduced in leakage current, and a malfunction which may occur in the capacitively coupled MOS type ESD protection circuit can be prevented.

Although the embodiments of the present invention have been described in detail with reference to the drawings, the present invention is not limited to these embodiments, and also includes designs and the like within the scope not deviating from the gist of the present invention.

Specifically, in these embodiments, the first terminal is the V_{DD} terminal. However, the present invention is not limited thereto. For example, the first terminal may be an input terminal, an output terminal, or the like.

FIG. 3B illustrates a modification in which a resistive element and a diode are connected to an NMOS transistor. However, the present invention is not limited thereto. It may be that only the diode is connected to the NMOS transistor and the resistive element is not connected to the NMOS transistor.

Furthermore, even if the LDD structure is adopted for the NMOS transistor, a sidewall spacer may not be formed.

What is claimed is:

1. An ESD protection circuit, connected in parallel with a protected circuit operating at a predetermined operating voltage between a first terminal and a second terminal, wherein the ESD protection circuit comprises:
an NMOS transistor, in which at least a drain is connected to the first terminal and a source is connected to the second terminal, wherein
a threshold voltage and a trigger voltage of a parasitic bipolar transistor of the NMOS transistor are higher than the operating voltage and lower than a breakdown voltage of the protected circuit and a gate insulating film.

2. The ESD protection circuit according to claim 1, wherein
a gate of the NMOS transistor is connected to the first terminal.

3. The ESD protection circuit according to claim 2, wherein
a resistive element is connected between the first terminal and the gate of the NMOS transistor.

4. The ESD protection circuit according to claim 3, wherein
a diode having an avalanche breakdown voltage higher than the operating voltage is connected between the second terminal and the gate of the NMOS transistor.

5. The ESD protection circuit according to claim 1, wherein
a gate of the NMOS transistor is in a floating state.

6. The ESD protection circuit according to claim 1, wherein
the NMOS transistor comprises:
a semiconductor substrate;
a P type well region, formed on a surface side of the semiconductor substrate;
an N type high concentration drain region and an N type high concentration source region, provided spaced apart over an upper part of the P type well region and having a higher impurity concentration than an impurity concentration of the P type well region;
a P type intermediate concentration region, provided in a region in contact with at least the N-type high concentration drain region and having a higher P type impurity concentration than the impurity concentration of the P type well region;
a gate insulating film, provided on a semiconductor surface between the N type high concentration drain region and the N type high concentration source region; and
a gate electrode, provided on the gate insulating film.

7. The ESD protection circuit according to claim 6, wherein
the P type intermediate concentration region is further in contact with the P type well region.

8. The ESD protection circuit according to claim 6, wherein
the P type intermediate concentration region is further provided in a channel region between the N type high concentration drain region and the N type high concentration source region.

9. The ESD protection circuit according to claim 8, wherein
a P type intermediate concentration channel region is provided on a surface of the semiconductor substrate between the N type high concentration drain region and the N type high concentration source region.

10. The ESD protection circuit according to claim 6, wherein
the NMOS transistor further comprises a DDD structure.

11. The ESD protection circuit according to claim 6, wherein
the NMOS transistor further comprises an LDD structure.

12. The ESD protection circuit according to claim 6, wherein
the NMOS transistor further comprises a sidewall spacer provided on a sidewall of the gate insulating film and a sidewall of the gate electrode.

13. A semiconductor device, wherein
the ESD protection circuit according to claim 1 and a protected circuit protected from electrostatic discharge by the ESD protection circuit are connected in parallel.
